(19) United States
(12) Patent Application Publication
(10) Pub. No.: US 2023/0225212 A1
(43) Pub. Date: Jul. 13, 2023

(54) METHOD OF MAKING PACKAGES WITH MULTI-LAYER PIEZOELECTRIC SUBSTRATE

(71) Applicant: Skyworks Solutions, Inc., Irvine, CA (US)

(72) Inventors: Rei Goto, Osaka-shi (JP); Hironori Fukuhara, Ibaraki-shi (JP)

(21) Appl. No.: 18/069,141

(22) Filed: Dec. 20, 2022

Related U.S. Application Data
(60) Provisional application No. 63/266,739, filed on Jan. 13, 2022.
(60) Provisional application No. 63/266,741, filed on Jan. 13, 2022.

(51) Int. Cl. H10N 30/072; H03H 3/08; H03H 9/02; H03H 9/64

(52) U.S. Cl. CPC H10N 30/072; H03H 3/08; H03H 9/02574; H03H 9/64

(57) ABSTRACT

A method of making an electronics package with a multi-layer piezoelectric substrate includes bonding a piezoelectric layer over a substrate. The method also includes applying a polyimide layer over an outer boundary of the piezoelectric layer so that the polyimide layer is interposed between the piezoelectric layer and a metal portion (e.g., of copper (Cu)) to inhibit (e.g., prevent) stresses from the metal layer damaging the piezoelectric layer.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

Embodiments of this disclosure relate to multi-layer piezoelectric substrates, and more particularly to electronic packages with multi-layer a piezoelectric substrate and methods of making the same.

### Description of Related Technology

Acoustic wave filters can be implemented in radio frequency electronic systems. For instance, filters in a radio frequency front end of a mobile phone can include acoustic wave filters in an electronics package. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators in a package arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

The packaging process for multilayer piezoelectric substrate packages can apply stresses to the piezoelectric layer that can result in reliability issues including cracking of the piezoelectric layer.

### SUMMARY

Accordingly, there is a need for an electronics package with a multi-layer piezoelectric substrate (e.g., a surface acoustic wave package, such as a SAW or TCSAW package) with improved reliability that can withstand the stresses, for example during the packaging process.

In accordance with one aspect of the disclosure, electronics package with a multi-layer piezoelectric substrate has a piezoelectric layer over a substrate. The outer boundary of the piezoelectric layer is covered with a polyimide layer so that the polyimide layer is interposed between the piezoelectric layer and a metal portion (e.g., of copper (Cu)) to inhibit (e.g., prevent) stresses from the metal layer damaging the piezoelectric layer.

In accordance with one aspect of the disclosure, an electronics package with a multi-layer piezoelectric substrate has a piezoelectric layer over a substrate. The outer boundary of the piezoelectric layer is covered with a polyimide layer, and a metal layer (e.g., of copper (Cu)) of the package is set back from the piezoelectric layer to inhibit (e.g., prevent) stresses from the metal layer damaging the piezoelectric layer.

In accordance with one aspect of the disclosure, a method of making an electronics package with a multi-layer piezoelectric substrate is provided. The method includes bonding a piezoelectric layer over a substrate. The method also includes applying a polyimide layer over an outer boundary of the piezoelectric layer so that the polyimide layer is interposed between the piezoelectric layer and a metal portion (e.g., of copper (Cu)) to inhibit (e.g., prevent) stresses from the metal layer damaging the piezoelectric layer.

In accordance with one aspect of the disclosure, a packaged acoustic wave component is provided. The packaged acoustic wave component comprises an acoustic wave device including a substrate, a piezoelectric layer disposed over at least a portion of the substrate and one or more signal lines. A thermally conductive structure is attached to one or both of the substrate and the one or more signal lines, the one or more signal lines interconnecting the piezoelectric layer and the thermally conductive structure. A dielectric layer is disposed over an outer edge portion of the piezoelectric layer and interposed between the piezoelectric layer and the thermally conductive structure to thereby reduce a stress on the piezoelectric layer from the thermally conductive structure.

In accordance with another aspect of the disclosure, a radio frequency module is provided. The radio frequency module comprises a package substrate and a packaged acoustic wave component. The packaged acoustic wave component comprises an acoustic wave device including a substrate, a piezoelectric layer disposed over at least a portion of the substrate and one or more signal lines. A thermally conductive structure is attached to one or both of the substrate and the one or more signal lines, the one or more signal lines interconnecting the piezoelectric layer and the thermally conductive structure. A dielectric layer is disposed over an outer edge portion of the piezoelectric layer and interposed between the piezoelectric layer and the thermally conductive structure to thereby reduce a stress on the piezoelectric layer from the thermally conductive structure. The radio frequency module also comprises additional circuitry, the packaged acoustic wave component and additional circuitry disposed on the package substrate.

In accordance with another aspect of the disclosure, a wireless communication device is provided. The wireless communication device comprises an antenna and a front end module including one or more packaged acoustic wave components configured to filter a radio frequency signal associated with the antenna. Each packaged acoustic wave component includes an acoustic wave device including a substrate, a piezoelectric layer disposed over at least a portion of the substrate and one or more signal lines. A thermally conductive structure is attached to one or both of the substrate and the one or more signal lines, the one or more signal lines interconnecting the piezoelectric layer and the thermally conductive structure. A dielectric layer is disposed over an outer edge portion of the piezoelectric layer and interposed between the piezoelectric layer and the thermally conductive structure to thereby reduce a stress on the piezoelectric layer from the thermally conductive structure.

In accordance with another aspect of the disclosure, a method of making a packaged acoustic wave component is provided. The method includes forming an acoustic wave device including forming or providing a substrate, forming or providing a piezoelectric layer over at least a portion of the substrate, and forming or providing one or more signal lines. The method also includes forming a dielectric layer over an outer edge portion of the piezoelectric layer. The method also includes attaching a thermally conductive structure to the substrate and the one or more signal lines, the one or more signal lines interconnecting the piezoelectric layer and the thermally conductive structure, the dielectric layer interposed between the piezoelectric layer and the thermally conductive structure to thereby reduce a stress on the piezoelectric layer from the thermally conductive structure.

In accordance with another aspect of the disclosure, a method of making a radio frequency module is provided. The method comprises forming or providing a package substrate. The method also comprises forming or providing a packaged acoustic wave component. Forming or providing the packaged acoustic wave component includes forming an acoustic wave device including forming or providing a substrate, forming or providing a piezoelectric layer over at least a portion of the substrate, and forming or providing one or more signal lines. The method also includes forming a dielectric layer over an outer edge portion of the piezoelectric layer. The method also includes attaching a thermally conductive structure to the substrate and the one or more signal lines, the one or more signal lines interconnecting the piezoelectric layer and the thermally conductive structure, the dielectric layer interposed between the piezoelectric layer and the thermally conductive structure to thereby reduce a stress on the piezoelectric layer from the thermally conductive structure. The method also includes attaching additional circuitry and the packaged acoustic wave component to the package substrate.

### BRIEF DESCRIPTION OF THE DRAWINGS

Embodiments of this disclosure will now be described, by way of non-limiting example, with reference to the accompanying drawings.

FIG. 1 illustrates a schematic top view of an electronics package with a multi-layer piezoelectric substrate (MPS) structure.

FIG. 1A illustrates a schematic partial cross-sectional side view of the package of FIG. 1 in a non-electrically connected portion of the package along section A-A.

FIG. 1B illustrates a schematic partial cross-sectional side view of the package of FIG. 1 in an electrically connected portion of the package along section B-B.

FIG. 2 illustrates a schematic top view of an electronics package with a multi-layer piezoelectric substrate (MPS) structure.

FIG. 2A illustrates a schematic partial cross-sectional side view of the package of FIG. 2 in a non-electrically connected portion of the package along section A-A.

FIG. 2B illustrates a schematic partial cross-sectional side view of the package of FIG. 2 in an electrically connected portion of the package along section B-B.

FIG. 3 illustrates a schematic top view of an electronics package with a multi-layer piezoelectric substrate (MPS) structure.

FIG. 3A illustrates a schematic partial cross-sectional side view of the package of FIG. 3 in a non-electrically connected portion of the package along section A-A.

FIG. 3B illustrates a schematic partial cross-sectional side view of the package of FIG. 3 in an electrically connected portion of the package along section B-B.

FIG. 4 illustrates a schematic top view of an electronics package with a multi-layer piezoelectric substrate (MPS) structure.

FIG. 4A illustrates a schematic partial cross-sectional side view of the package of FIG. 4 in a non-electrically connected portion of the package along section A-A.

FIG. 4B illustrates a schematic partial cross-sectional side view of the package of FIG. 4 in an electrically connected portion of the package along section B-B.

FIG. 5A illustrates a schematic partial cross-sectional side view of the package of FIG. 1.

FIG. 5B shows a graph of stress versus distance for the package in FIG. 5A.

FIG. 6A illustrates a schematic partial cross-sectional side view of an electronics package with a multi-layer piezoelectric substrate.

FIG. 6B shows a graph of stress versus distance for the package in FIG. 6A.

FIG. 7A illustrates a schematic partial cross-sectional side view of an electronics package with a multi-layer piezoelectric substrate.

FIG. 7B shows a graph of stress versus distance for the package in FIG. 7A.

FIG. 8A illustrates a schematic partial cross-sectional side view of an electronics package with a multi-layer piezoelectric substrate.

FIG. 8B shows a graph of stress versus distance for the package in FIG. 8A.

FIG. 9A illustrates a schematic partial cross-sectional side view of an electronics package with a multi-layer piezoelectric substrate.

FIG. 9B shows a graph of stress versus distance for the package in FIG. 9A having no polyimide layer over the piezoelectric layer.

FIG. 9C shows a graph of stress versus distance for the package in FIG. 9A having a 1 um polyimide layer over the piezoelectric layer.

FIG. 9D shows a graph of stress versus distance for the package in FIG. 9A having a 2 um polyimide layer over the piezoelectric layer.

FIG. 9E shows a graph of stress versus distance for the package in FIG. 9A having a 3 um polyimide layer over the piezoelectric layer.

FIG. 10A illustrates a schematic partial cross-sectional side view of an electronics package with a multi-layer piezoelectric substrate.

FIG. 10B shows a graph of stress versus distance for the package in FIG. 10A having no polyimide layer over the piezoelectric layer.

FIG. 10C shows a graph of stress versus distance for the package in FIG. 10A having a 1 um polyimide layer over the piezoelectric layer.

FIG. 10D shows a graph of stress versus distance for the package in FIG. 10A having a 2 um polyimide layer over the piezoelectric layer.

FIG. 10E shows a graph of stress versus distance for the package in FIG. 10A having a 3 um polyimide layer over the piezoelectric layer.

FIG. 11 is a schematic diagram of a radio frequency module that includes a surface acoustic wave resonator according to an embodiment.

FIG. 12 is a schematic diagram of a radio frequency module that includes filters with surface acoustic wave resonators according to an embodiment.

FIG. 13 is a schematic block diagram of a module that includes an antenna switch and duplexers that include a surface acoustic wave resonator according to an embodiment.

FIG. 14A is a schematic block diagram of a module that includes a power amplifier, a radio frequency switch, and duplexers that include a surface acoustic wave resonator according to an embodiment.

FIG. 14B is a schematic block diagram of a module that includes filters, a radio frequency switch, and a low noise amplifier according to an embodiment.

FIG. 15A is a schematic block diagram of a wireless communication device that includes a filter with a surface acoustic wave resonator in accordance with one or more embodiments.

FIG. 15B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. SAW devices include SAW resonators, SAW delay lines, and multi-mode SAW (MMS) filters (e.g., double mode SAW (DMS) filters). Any features of the SAW resonators and/or devices discussed herein can be implemented in any suitable SAW device.

In general, high quality factor (Q), large effective electromechanical coupling coefficient (k²), high frequency ability, and spurious free response can be significant aspects for acoustic wave elements to enable low-loss filters, delay lines, stable oscillators, and sensitive sensors.

Multi-layer piezoelectric substrate (MPS) SAW resonators can thermally insulate an interdigital transducer electrode and a piezoelectric layer. By reducing dissipative thermal impedance of the SAW device, the ruggedness and power handling can be improved.

Some MPS SAW resonators have achieved high Q by confining energy and good thermal dissipation using a silicon (Si) support layer. However, such approaches have encountered technical challenges related to undesirable higher frequency spurious responses.

Some other MPS SAW resonators have achieved high Q by confining energy and have also reduced higher frequency spurious responses. However, such approaches have encountered relatively low thermal heat dissipation.

Aspects of the present disclosure relate to SAW resonators that include a support substrate or layer (e.g., a single crystal supporting substrate), a functional layer (e.g., a dielectric layer) over the support substrate or layer, a piezoelectric layer (e.g., a lithium niobate (LN or LiNbO3) layer or a lithium tantalate (LT or LiTaO3) layer) over the functional layer, and an interdigital transducer (IDT) electrode over the piezoelectric layer. Such SAW resonators can also include a temperature compensation layer (e.g., silicon dioxide (SiO2) layer) over the IDT electrode in certain embodiments. The SAW resonators can also include an adhesion layer disposed between the support substrate and the functional layer and/or an adhesion layer between the functional layer and the piezoelectric layer, in certain applications.

SAW resonators with the functional layer and the support layer or substrate can beneficially provide a relatively high effective electromechanical coupling coefficient (k²), a relatively high quality factor (Q), a relatively high power durability and thermal dissipation, and reduced high frequency spurious responses. The high coupling coefficient (k²) can be beneficial for relatively wide bandwidth filters. The high quality factor (Q) can beneficially lead to a relatively low insertion loss. The reduced high frequency spurious may make the SAW resonators compatible with multiplexing with higher frequency bands.

In an embodiment, an MPS SAW resonator includes a piezoelectric layer over a functional layer over a silicon support substrate or layer. The silicon support substrate can reduce thermal impedance of the MPS SAW resonator. The functional layer can be a single crystal layer arranged to confine acoustic energy and lower a higher frequency spurious response. The piezoelectric layer, the functional layer, and the silicon support substrate can all be single crystal layers.

Embodiments of MPS SAW resonators (e.g., packages) will now be discussed. Any suitable principles and advantages of these MPS SAW resonators can be implemented together with each other in an MPS SAW resonator and/or in an acoustic wave filter. MPS SAW resonators (e.g., packages) disclosed herein can have lower loss than certain bulk acoustic wave devices.

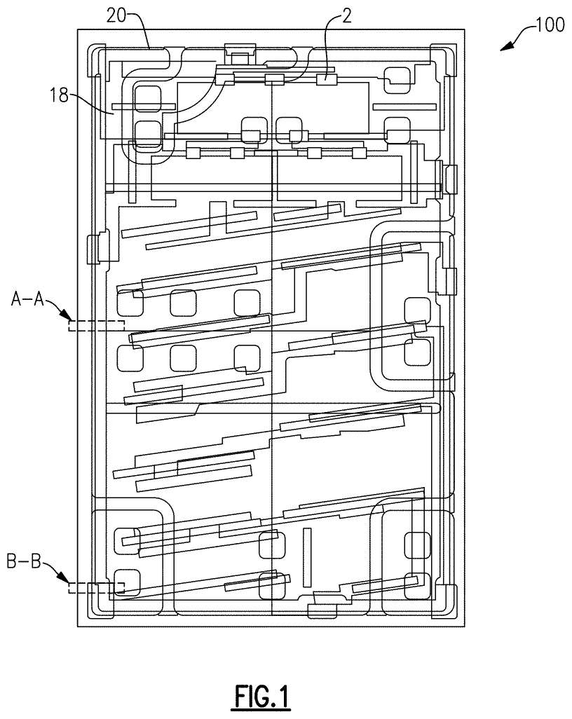

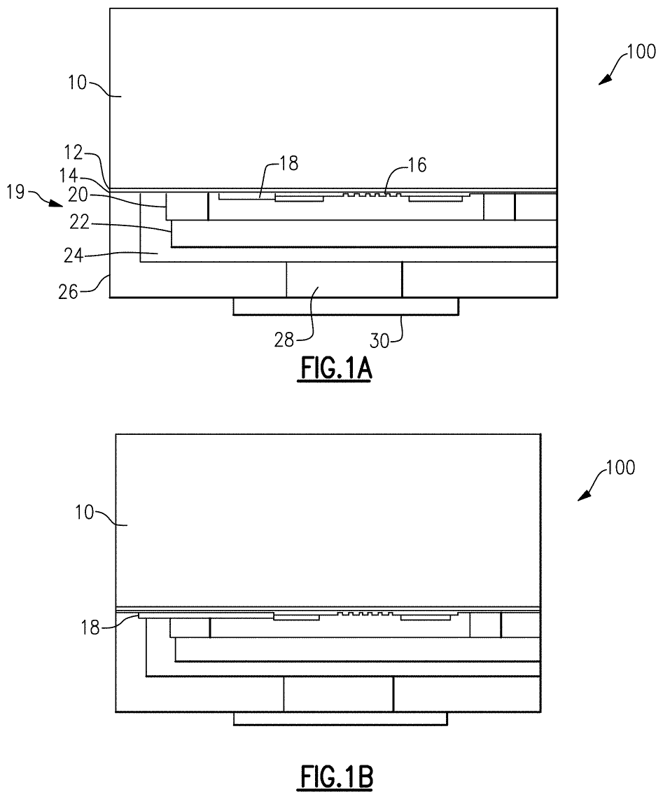

FIG. 1 illustrates a top view of an electronics package 100, FIG. 1A shows a partial cross-section of the package 100 along section A-A, and FIG. 1B shows a partial cross-section of the package 100 along section B-B. The package 100 can include polyimide 2 in one or more internal locations of the package 100. As further discussed below, the outer portion or boundary of the package 100 includes a pillar 20 and metal layer 18 that extends over a portion of a piezoelectric layer and/or interdigital transducer electrode (IDT).

With reference to FIGS. 1A-1B, the package 100 includes a substrate 10, an additional (e.g., functional, dielectric) structure or layer 12 disposed over (e.g., bonded to) the substrate 10, and a piezoelectric structure or layer 14 disposed over (e.g. bonded to) the dielectric layer 12. An interdigital transducer electrode (IDT) 16 is disposed over (e.g., mounted to, bonded to) the piezoelectric structure or layer 14. One or more signal lines or metal layer 18 can be disposed on (e.g., connected to) the piezoelectric layer 14 (e.g., connected to the IDT 16).

With continued reference to FIGS. 1A-1B, a thermally conductive structure or package 19 is connected to the substrate 10, for example via the functional/dielectric layer 12, piezoelectric layer 14 and signal line or metal layer 18. The thermally conductive structure or package 19 includes a metal portion 24 (e.g., of copper (Cu)) that defines a cavity (e.g., open or hollow cavity, air cavity) over the IDT 16, a cavity roof or layer 22 disposed over at least a portion of the metal portion 24 and spaced from the IDT 16, and a pillar 20 between the cavity roof or layer 22 and the piezoelectric structure or layer 14. A dielectric overcoat or filler 26 is disposed over at least a portion of the metal portion 24. a via 28 extends from through the filler 26 to an external terminal (e.g., solder connection) 30 to interconnect the external terminal 30 with the metal portion 24. One drawback of the package 100 is that the piezoelectric structure or layer 14 can crack based at least on stresses from the metal portion 24 (e.g., from direct contact between the metal portion 24 shown in FIG. 1A, or from indirect contact via the metal layer 18 shown in FIG. 1B).

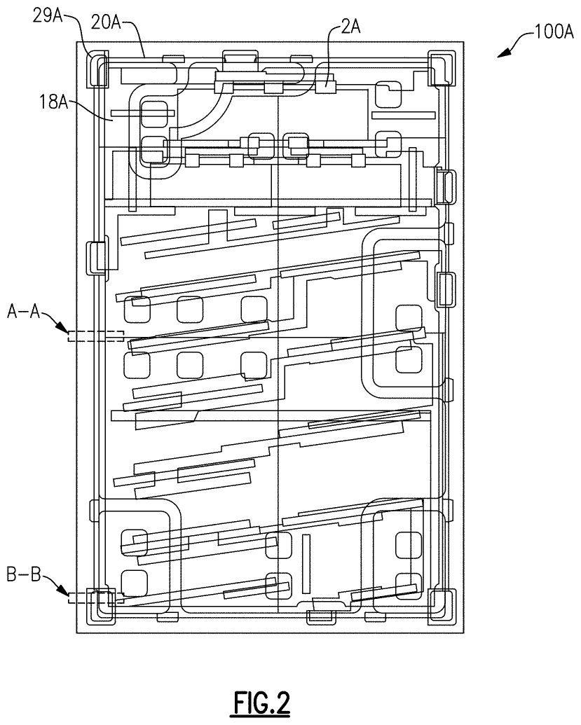

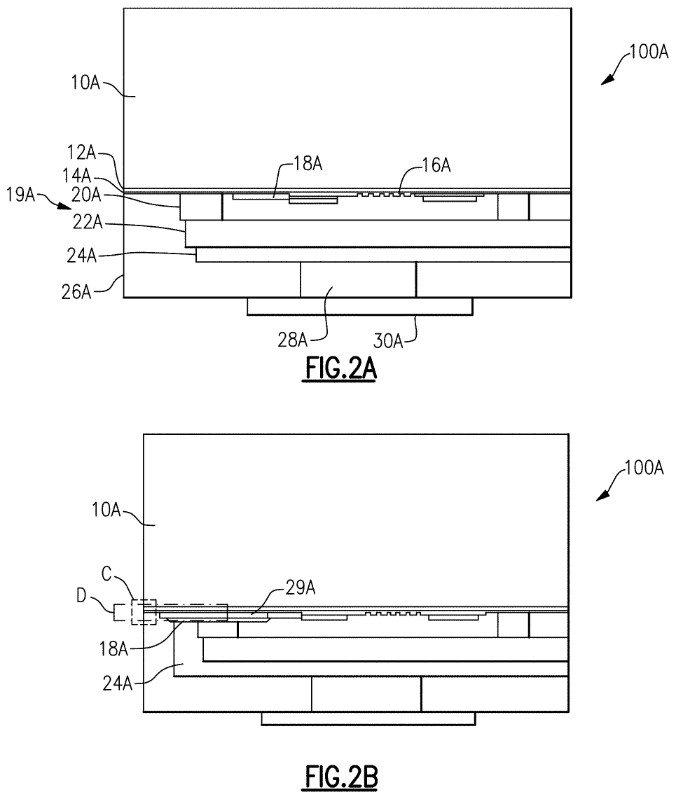

The inventors have recognized that improved reliability of electronic packages with multi-layer piezoelectric substrates can be achieved by improvements in the design of the package to reduce stress on the piezoelectric structure or layer, as provided for in the implementations discussed below. FIG. 2 shows a top view of an electronics package 100A, FIG. 2A shows a partial cross-section of the package 100A along section A-A, and FIG. 2B shows a partial cross-section of the package 100A along section B-B. The package 100A is similar to the package 100 of FIGS. 1-1B. Thus, reference numerals used to designate the various components of the package 100A are identical to those used for identifying the corresponding components of the package 100 in FIGS. 1-1B, except that an “A” has been added to the numerical identifier. Therefore, the structure and description for the various features and components of the package 100 in FIGS. 1-1B are understood to also apply to the corresponding features of the package 100A in FIGS. 2-2B, except as described below.

The package 100A differs from the package 100 in that the metal portion 24A is set back (e.g., spaced, separated) from the piezoelectric structure or layer 14A so that the metal portion 24A does not contact the piezoelectric structure or layer 14A in the non-electrically connected portion (or area) of the package 100A, as shown in FIG. 2A. Additionally, in the electrically connected portion of the package 100A, shown in FIG. 2B, a dielectric layer (e.g., of polyimide) 29A is disposed over the piezoelectric layer 14A (e.g., interposed between the metal portion 24A and the signal line(s) or metal layer 18A and the piezoelectric layer 14A). Accordingly, the dielectric layer 29A provides a buffer between the metal portion (e.g., of copper (Cu)) and the piezoelectric layer 14A (and a buffer between the signal line(s) or metal layer 18A and the piezoelectric layer 14A), which results in a reduction in stress the piezoelectric layer 14A is subjected to, as discussed further below. Such a reduction in stress can advantageously inhibit (e.g. prevent) deformation and damage (e.g., cracks) to the piezoelectric layer 14A (and to the functional layer 12A) due to stresses applied on the package 100A, for example resulting from a different thermal expansion of the substrate 10A and the thermally conductive structure or package 19A (e.g., during heat cycle testing).

In the illustrated implementation, the functional layer 12A and piezoelectric layer 14A extend to the outer boundary of the support substrate 10A or street. In another implementation, the piezoelectric layer 14A (and functional layer 12A) are etched from the dicing street (e.g., section in box C of the piezoelectric layer 14A and functional layer 12A are removed) so that they do not extend to the outer boundary of the support substrate 10A. In another implementation, the piezoelectric layer 14A (and functional layer 12A) are etched to a location inward of the metal portion 24A (e.g., section in box D of the piezoelectric layer 14A and functional layer 12A are removed). The piezoelectric layer 14A (and dielectric layer 12A) can therefore have an outer edge or perimeter that is spaced from (e.g., spaced inward from) the metal portion 24A (e.g., from an inner surface of the metal portion 24A), for example by a distance of between 5 microns (0.005 mm) and 15 microns (0.015 mm), such as 5 microns, 10 microns and 15 microns. Spacing the outer edge of the piezoelectric layer 14A and of the functional layer 12A from the metal portion 24A (e.g., by removing portions in boxes C or D in FIG. 2B) can advantageously inhibit (e.g., prevent) damage to the resulting dies during dicing (e.g., with a mechanical saw) of the wafer, the dies including the substrate 10A, functional layer 12A and piezoelectric layer 14A used for the package 100A.

The support substrate 10A can include (e.g., be made of, consist of) silicon (Si). In another example, the substrate 10A can be made of poly-silicon. In another example, the substrate 10A can be made of amorphous silicon. In another example, the substrate 10A can be made of silicon nitride (SiN). In another example, the substrate 10A can be made of Sapphire. In another example, the substrate 10A can be made of quartz. In another example, the substrate 10A can be made of aluminum nitride (AlN). In another example, the substrate 10A can be made of polycrystalline ceramic (Mg₂O₄). In another implementation, the substrate 10A can be made of diamond. However, the substrate 10A can be made of other suitable high impedance materials. An acoustic impedance of the substrate 10A can be higher than an acoustic impedance of the piezoelectric structure or layer 212. In another implementation the support substrate 10A can include a multilayer structure. For example, the support substrate can have a two-layer structure with single crystal silicon (Si) and polysilicon.

The functional (e.g., temperature compensation, dielectric) structure or layer 12A can have a lower acoustic impedance than the substrate 10A. The functional structure or layer 12A can increase adhesion between the substrate 10A and the piezoelectric structure or layer 14A of the package 100A. Alternatively or additionally, the functional structure or layer 12A can increase heat dissipation of the package 100A. The functional structure or layer 12A can be made of silicon dioxide (SiO2). In some implementations, the functional structure or layer is excluded from the package 100A (e.g., the piezoelectric layer 14A is disposed on, adjacent to or in contact with the substrate 10A).

In one implementation, the piezoelectric layer 14A can be made of lithium niobate (LN or LiNbO3). In another implementation, the piezoelectric layer 14A can be made of lithium tantalate (LT or LiTaO3). One or more resonators (e.g., including an interdigital transducer (IDT) electrode 16A, for example, between two reflectors) can be disposed on (e.g., attached or mounted to) the piezoelectric layer 14A.

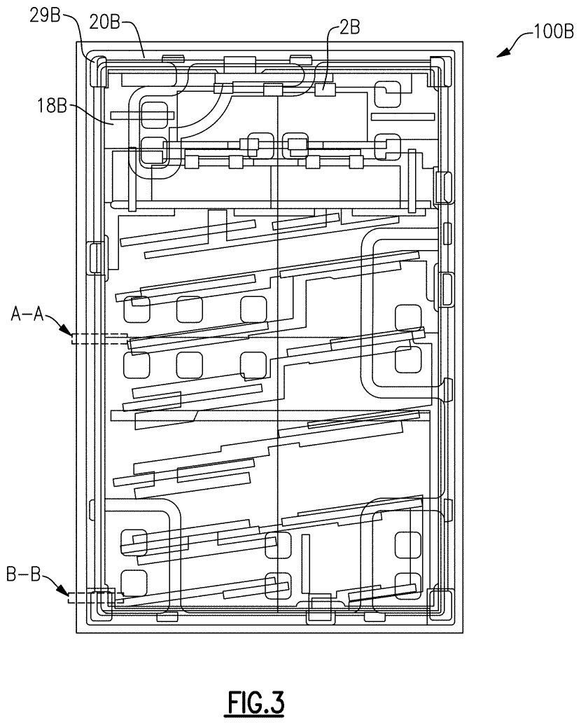

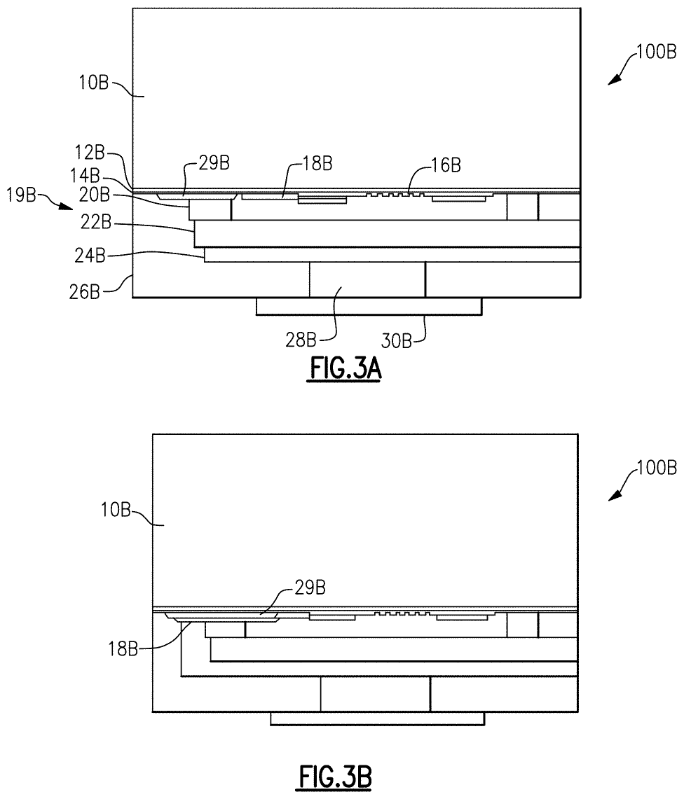

FIG. 3 shows a top view of an electronics package 100B, FIG. 3A shows a partial cross-section of the package 100B along section A-A, and FIG. 3B shows a partial cross-section of the package 100B along section B-B. The package 100B is similar to the package 100A of FIGS. 2-2B. Thus, reference numerals used to designate the various components of the package 100B are identical to those used for identifying the corresponding components of the package 100A in FIGS. 2-2B, except that a “B”, instead of an “A”, has been added to the numerical identifier. Therefore, the structure and description for the various features and components of the package 100A in FIGS. 2-2B, which are based on the structure and description for the various features and components of the package 100 in FIGS. 1-1B, are understood to also apply to the corresponding features of the package 100B in FIGS. 3-3B, except as described below.

The package 100B differs from the package 100A in that the dielectric (e.g., polyimide) layer 29B extends along an entire perimeter (e.g., periphery) of the package 100B. As shown in FIG. 3A, the dielectric layer 29B is disposed over the piezoelectric layer 14B (e.g. interposed between the pillar 20B and the piezoelectric layer 14B) in the non-electrically connected portion of the package 100B. As with the package 100A, the dielectric layer 29B (e.g., of polyimide) is disposed over the piezoelectric layer 14B (e.g., interposed between the metal portion 24B and the signal line(s) or metal layer 18B and the piezoelectric layer 14B) in the electrically connected portion of the package 100B (see FIG. 3B). Accordingly, the dielectric layer 29B provides a buffer between the metal portion (e.g., of copper (Cu)) and the piezoelectric layer 14B (and a buffer between the signal line(s) or metal layer 18B and the piezoelectric layer 14B), which results in a reduction in stress the piezoelectric layer 14B is subjected to, as discussed further below. One of skill in the art will recognize that in other implementations the package 100B can have the piezoelectric layer 14B (and functional layer 12B) etched in the same manner described above in connection with FIG. 2B (to remove the portion of the piezoelectric layer 14B and (optionally) the functional layer 12B shown in boxes C and D in FIG. 2B).

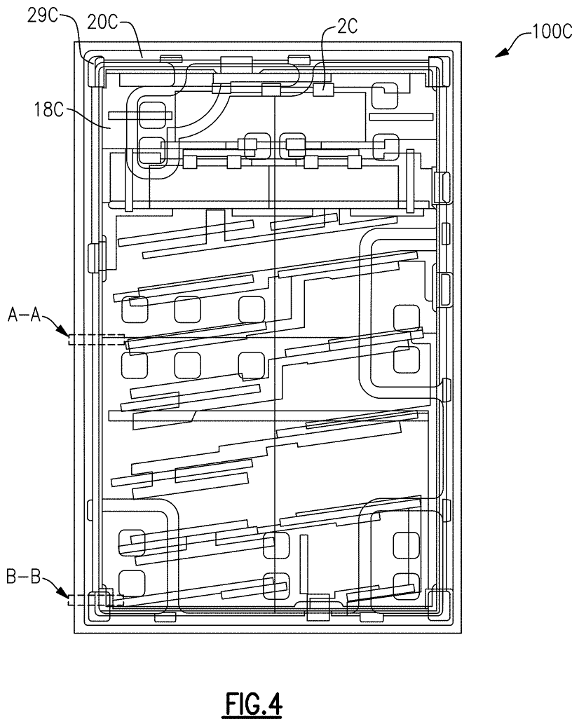

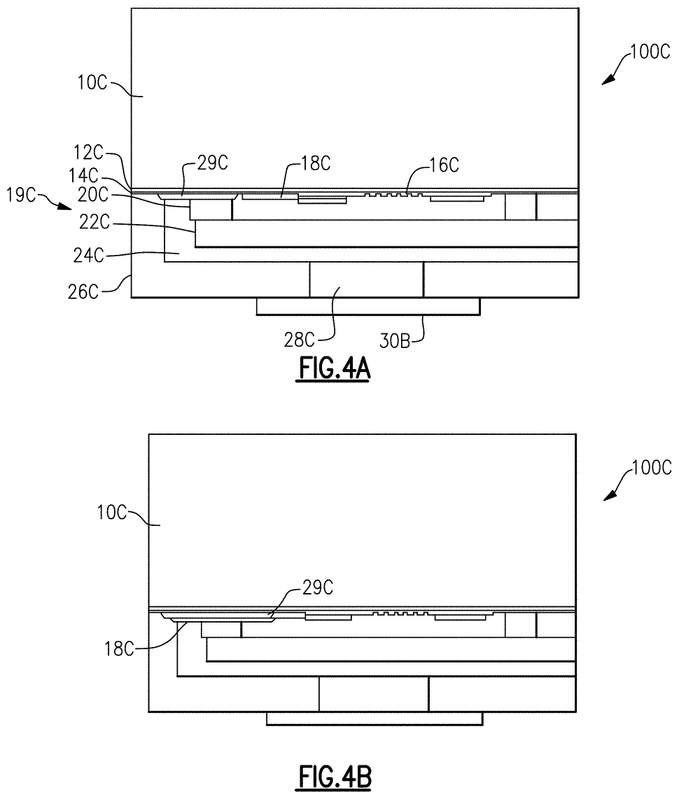

FIG. 4 shows a top view of an electronics package 100C, FIG. 4A shows a partial cross-section of the package 100C along section A-A, and FIG. 4B shows a partial cross-section of the package 100C along section B-B. The package 100C is similar to the package 100B of FIGS. 3-3B. Thus, reference numerals used to designate the various components of the package 100C are identical to those used for identifying the corresponding components of the package 100B in FIGS. 3-3B, except that a “C”, instead of a “B”, has been added to the numerical identifier. Therefore, the structure and description for the various features and components of the package 100B in FIGS. 3-3B, which are based on the structure and description for the various features and components of the package 100A in FIGS. 2-2B and package 100 in FIGS. 1-1B, are understood to also apply to the corresponding features of the package 100C in FIGS. 4-4B, except as described below.

The package 100C differs from the package 100B in that the metal portion 24C is not set back (e.g., spaced) from the piezoelectric layer 14C in the non-electrically connected portion of the package 100C, as shown in FIG. 4A. Therefore, in the non-electrically connected portion shown in FIG. 4A, like in the electrically connected portion of the package 100C shown in FIG. 4B, the [0076] the dielectric layer 29C (e.g., of polyimide) is disposed over the piezoelectric layer 14C (e.g., interposed between the metal portion 24C and the piezoelectric layer 14C). Accordingly, the dielectric layer 29C (e.g., of polyimide) provides a buffer between the metal portion (e.g., of copper (Cu)) 24C and the piezoelectric layer 14C, which results in a reduction in stress the piezoelectric layer 14C is subjected to, as discussed further below. One of skill in the art will recognize that in other implementations the package 100C can have the piezoelectric layer 14C (and functional layer 12C) etched in the same manner described above in connection with FIG. 2B (to remove the portion of the piezoelectric layer 14C and (optionally) the functional layer 12C shown in boxes C and D in FIG. 2B).

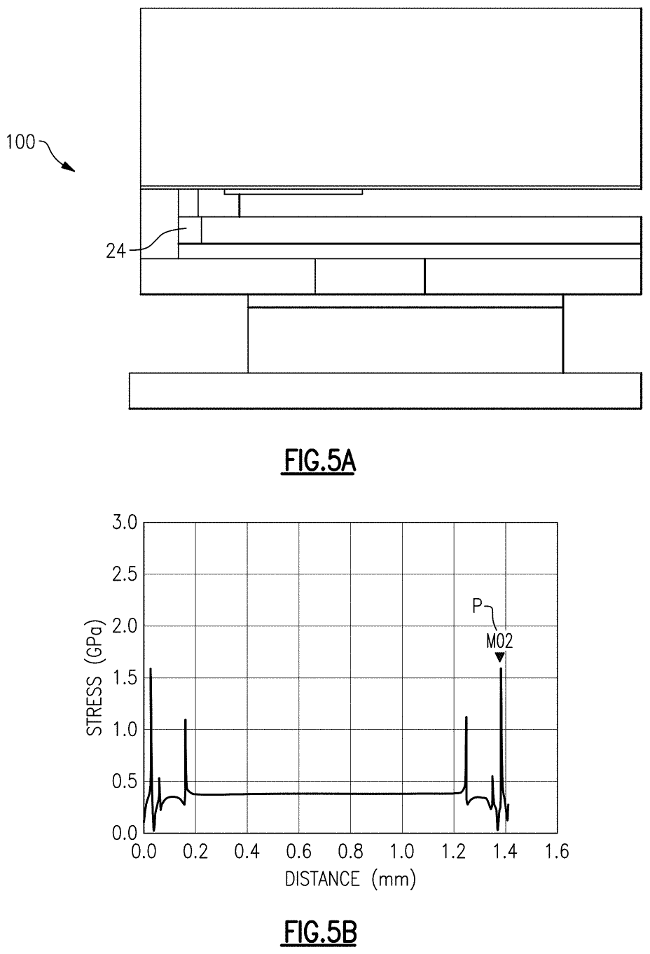

FIG. 5A shows a schematic partial cross-sectional side view of the package 100 with the metal portion 24 extending to the piezoelectric layer. FIG. 5B shows a graph of a stress simulation for the package 100. The graph shows stress (in giga Pascals or GPa) versus distance (in mm) across the width of the package 100. The graph indicates that the package 100 experiences a peak P stress of approximately 1.59 GPa at the edge of the metal portion 24.

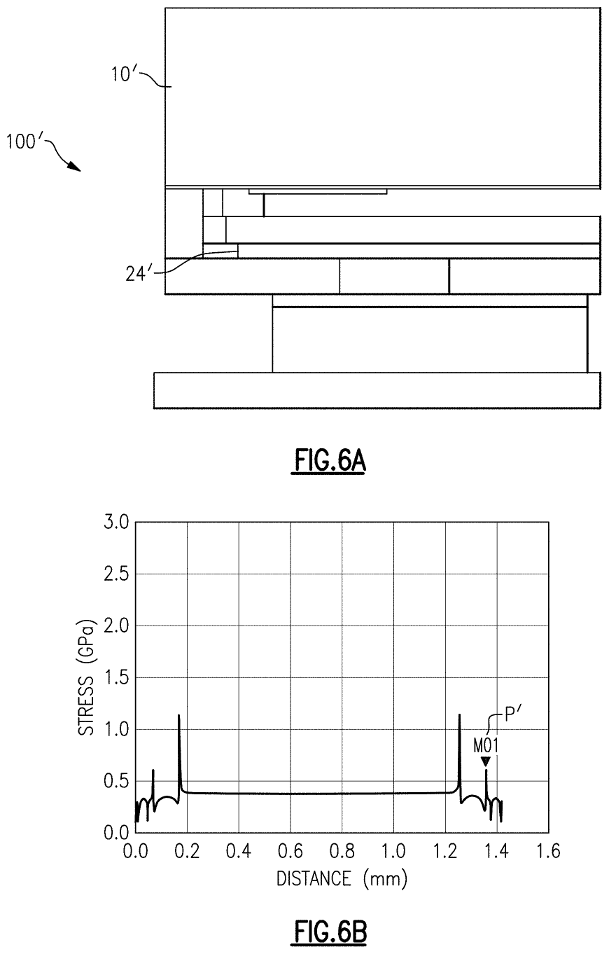

FIG. 6A shows a schematic partial cross-sectional side view of a package 100′ with the metal portion 24′ set back from the piezoelectric layer (e.g., in a non-electrically connected portion of the package 100′). FIG. 6B shows a graph of a stress simulation for the package 100′. The graph shows stress (in giga Pascals or GPa) versus distance (in mm) across the width of the package 100′. The graph indicates that the package 100′ experiences a peak P′ stress at the edge of the package of approximately 0.61 GPa, or approximately a 61% reduction in peak stress as compared with the package 100 in FIGS. 5A-5B.

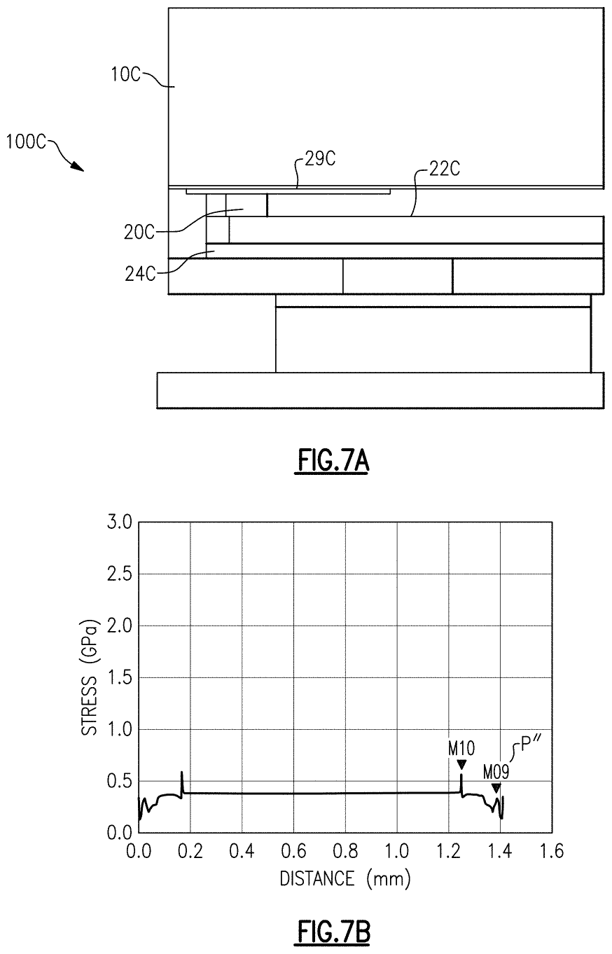

FIG. 7A shows a schematic partial cross-sectional side view of the package 100C with the dielectric layer 29C (e.g. polyimide) interposed between the metal portion 24C and the piezoelectric layer. FIG. 7B shows a graph of a stress simulation for the package 100C. The graph shows stress (in giga Pascals or GPa) versus distance (in mm) across the width of the package 100C. The graph indicates that the package 100C experiences a peak P″ stress at the edge of the package of approximately 0.34 GPa, or approximately a 79% reduction in peak stress as compared with the package 100 in FIGS. 5A-5B.

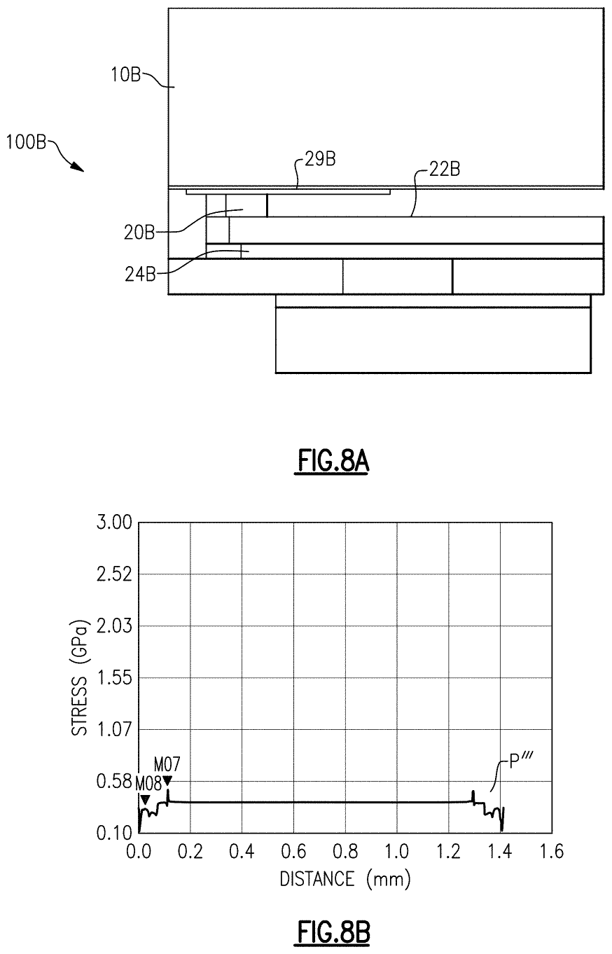

FIG. 8A shows a schematic partial cross-sectional side view of the package 100B with the dielectric layer 29B (e.g. polyimide) interposed between the metal portion 24B and the piezoelectric layer and the metal portion 24B set back (e.g., spaced) from the piezoelectric layer (e.g., in the non-electrically connected portion of the package 100B). FIG. 8B shows a graph of a stress simulation for the package 100B. The graph shows stress (in giga Pascals or GPa) versus distance (in mm) across the width of the package 100B. The graph indicates that the package 100B experiences a peak P′″ stress at the edge of the package of approximately 0.33 GPa, or approximately a 79% reduction in peak stress as compared with the package 100 in FIGS. 5A-5B. Accordingly, the use of the dielectric buffer layer 29B, 29C and/or set back of the metal portion 24B, 24′ results in significant reduction in stress on the piezoelectric structure of layer of the package, resulting in increased reliability of the package.

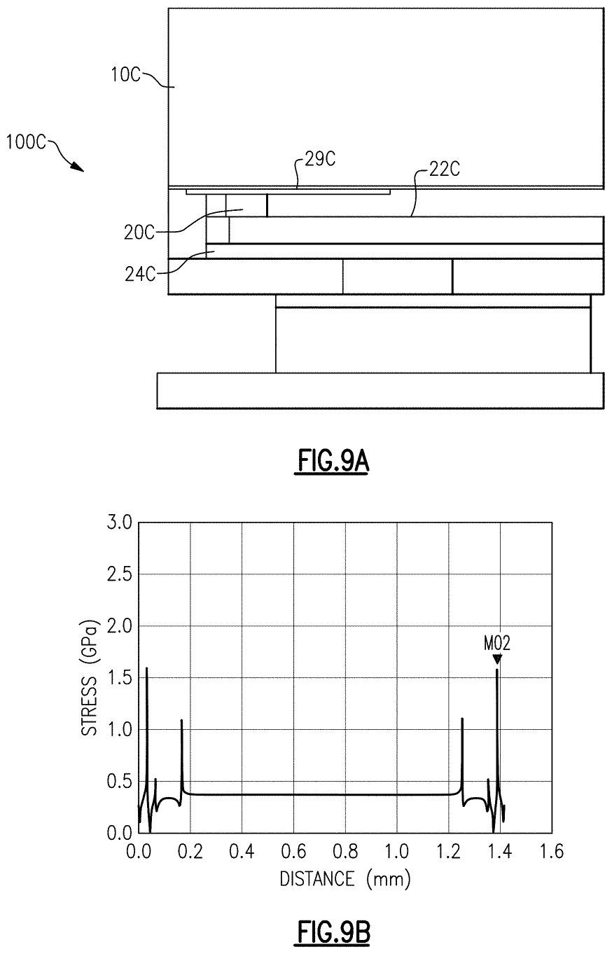

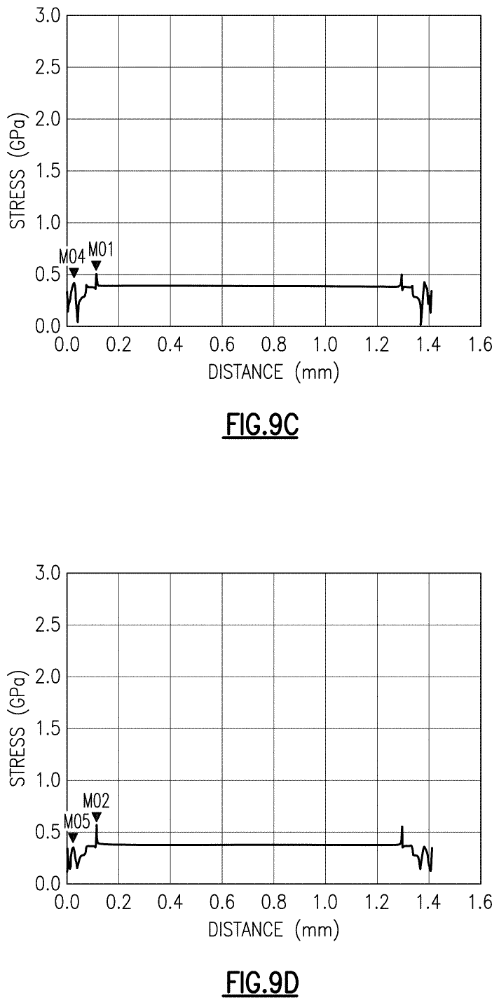

FIG. 9A shows a schematic partial cross-sectional side view of the package 100C with the dielectric layer 29C (e.g. polyimide) interposed between the metal portion 24C and the piezoelectric layer. FIGS. 9B-9E show graphs of a stress simulation for the package 100C for different thicknesses of the dielectric (e.g., polyimide) layer 29C. In FIG. 9B, there is no dielectric layer in the package 100C, and the graph indicates that the package experiences a peak stress of approximately 1.59 GPa at the edge of the metal portion 24C (e.g., the package has the same performance as shown above in FIG. 5B). In FIG. 9C, the dielectric (e.g., polyimide) layer 29C of the package 100C has a thickness of 1 um, and the graph indicates that the package 100C experiences a peak stress at the edge of the package of approximately 0.42 GPa, or approximately a 74% reduction in peak stress over the same package without any dielectric layer over the piezoelectric layer or structure. In FIG. 9D, the dielectric (e.g., polyimide) layer 29C of the package 100C has a thickness of 2 um, and the graph indicates that the package 100C experiences a peak stress at the edge of the package of approximately 0.35 GPa, or approximately a 78% reduction in peak stress over the same package without any dielectric layer over the piezoelectric layer or structure. In FIG. 9E, the dielectric (e.g., polyimide) layer 29C of the package 100C has a thickness of 3 um, and the graph indicates that the package 100C experiences a peak stress at the edge of the package of approximately 0.33 GPa, or approximately a 79% reduction in peak stress over the same package without any dielectric layer over the piezoelectric layer or structure. Accordingly, use of a dielectric (e.g., polyimide) layer 29C of 1 um or greater in thickness over the piezoelectric layer or structure can result in significant reduction in the peak stress experienced by the piezoelectric layer of the package 100C.

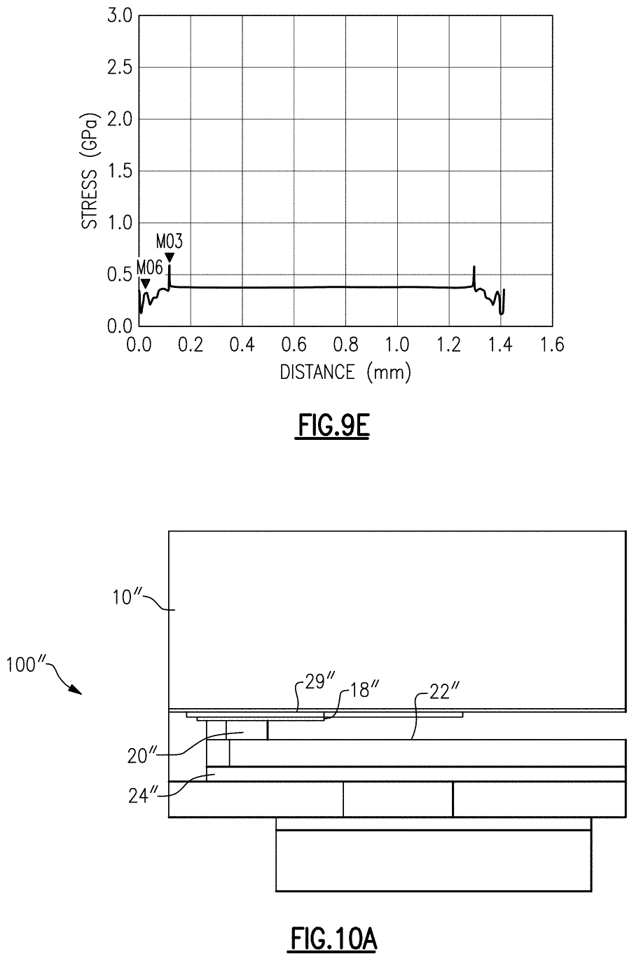

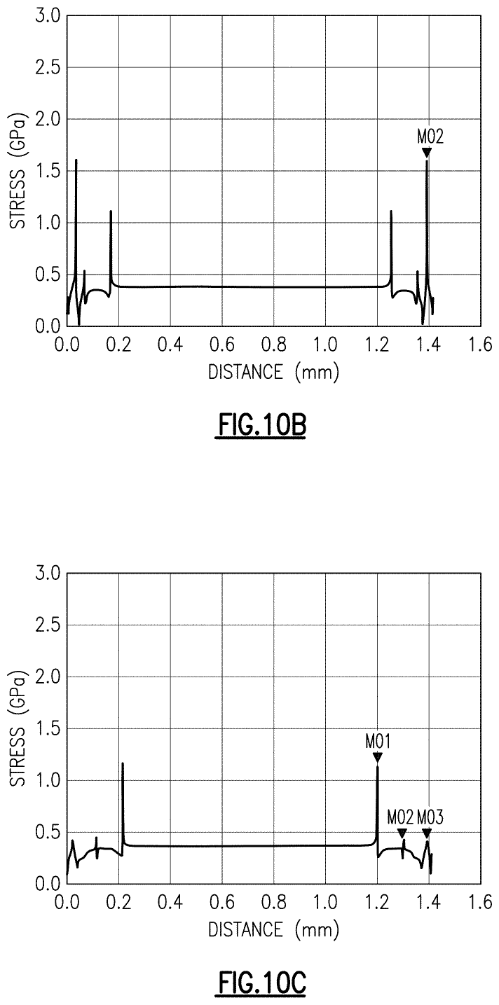

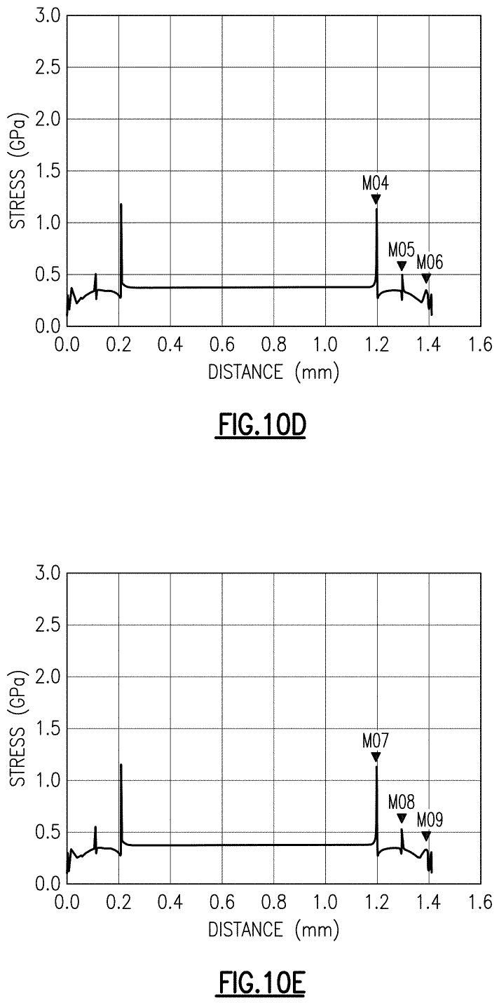

FIG. 10A shows a schematic partial cross-sectional side view of a package 100″ with the dielectric layer 29″ (e.g. polyimide) interposed between the metal portion 24″ and the piezoelectric layer, the dielectric layer 29″ also interposed between the signal or metal layer 18″ and the piezoelectric layer. The structure of the package 100″ is similar to that of the package 100C discussed above. FIGS. 10B-10E show graphs of a stress simulation for the package 100″ for different thicknesses of the dielectric (e.g., polyimide) layer 29″. In FIG. 10B, there is no dielectric layer in the package 100″, and the graph indicates that the package experiences a peak stress of approximately 1.59 GPa at the edge of the metal portion 24″ (e.g., the package has the same performance as shown above in FIG. 5B). In FIG. 10C, the dielectric (e.g., polyimide) layer 29″ of the package 100″ has a thickness of 1 um, and the graph indicates that the package 100″ experiences a peak stress at the edge of the package of approximately 0.42 GPa, or approximately a 74% reduction in peak stress over the same package without any dielectric layer over the piezoelectric layer or structure. In FIG. 10D, the dielectric (e.g., polyimide) layer 29″ of the package 100″ has a thickness of 2 um, and the graph indicates that the package 100″ experiences a peak stress at the edge of the package of approximately 0.36 GPa, or approximately a 77% reduction in peak stress over the same package without any dielectric layer over the piezoelectric layer or structure. In FIG. 10E, the dielectric (e.g., polyimide) layer 29″ of the package 100″ has a thickness of 3 um, and the graph indicates that the package 100″ experiences a peak stress at the edge of the package of approximately 0.34 GPa, or approximately a 79% reduction in peak stress over the same package without any dielectric layer over the piezoelectric layer or structure. Accordingly, use of a dielectric (e.g., polyimide) layer 29″ of 1 um or greater in thickness over the piezoelectric layer or structure can result in significant reduction in the peak stress experienced by the piezoelectric layer of the package 100″.

FIG. 11 is a schematic diagram of a radio frequency module 175 that includes an electronics package with a multi-layer piezoelectric substrate (e.g., a surface acoustic wave component) 176 according to an embodiment. The illustrated radio frequency module 175 includes the electronics package with a multi-layer piezoelectric substrate (e.g., SAW component) 176 and other circuitry 177. The electronics package with a multi-layer piezoelectric substrate (e.g., SAW component) 176 can include one or more SAW resonators with any suitable combination of features of the packages disclosed herein. The electronics package with a multi-layer piezoelectric substrate (e.g., SAW component) 176 can include a SAW die that includes SAW resonators.

The electronics package with a multi-layer piezoelectric substrate (e.g., SAW component) 176 shown in FIG. 11 includes a filter 178 and terminals 179A and 179B. The filter 178 includes one or more SAW resonators. The electronics package with a multi-layer piezoelectric substrate (e.g., SAW component) 176 can be implemented in accordance with any suitable principles and advantages of the packages 100A, 100B, 100C of FIGS. 2-4B. The terminals 179A and 178B can serve, for example, as an input contact and an output contact. The SAW component 176 and the other circuitry 177 are on a common packaging substrate 180 in FIG. 11. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

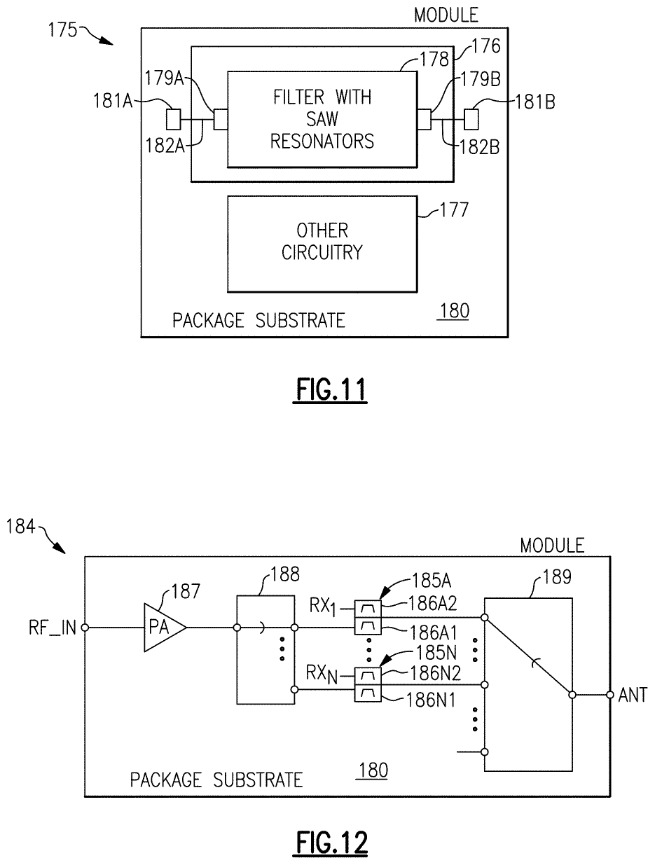

FIG. 12 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators or packages in accordance with any suitable principles and advantages disclosed herein. Similarly, one or more of the receive filters 186A2 to 186N2 can include one or more SAW resonators in accordance with any suitable principles and advantages disclosed herein. Although FIG. 12 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

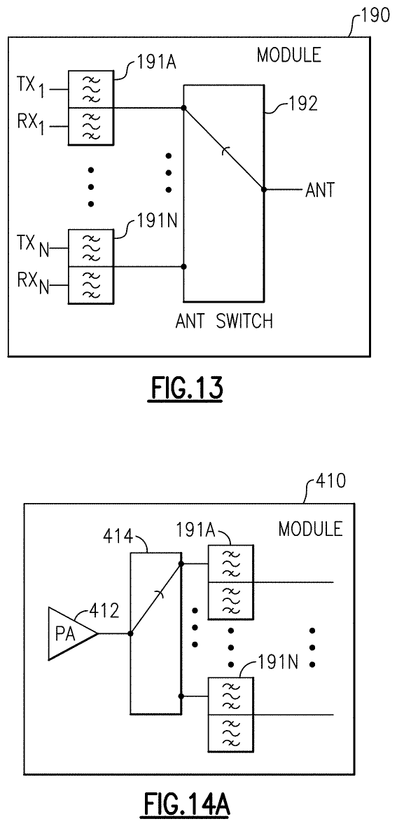

FIG. 13 is a schematic block diagram of a module 190 that includes duplexers 191A to 191N and an antenna switch 192. One or more filters of the duplexers 191A to 191N can include any suitable number of surface acoustic wave resonators or packages in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

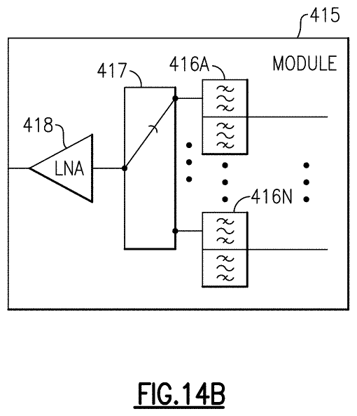

FIG. 14A is a schematic block diagram of a module 410 that includes a power amplifier 412, a radio frequency switch 414, and duplexers 191A to 191N in accordance with one or more embodiments. The power amplifier 412 can amplify a radio frequency signal. The radio frequency switch 414 can be a multi-throw radio frequency switch. The radio frequency switch 414 can electrically couple an output of the power amplifier 412 to a selected transmit filter of the duplexers 191A to 191N. One or more filters of the duplexers 191A to 191N can include any suitable number of surface acoustic wave resonators or packages in accordance with any suitable principles and advantages discussed herein. Any suitable number of duplexers 191A to 191N can be implemented.

FIG. 14B is a schematic block diagram of a module 415 that includes filters 416A to 416N, a radio frequency switch 417, and a low noise amplifier 418 according to an embodiment. One or more filters of the filters 416A to 416N can include any suitable number of acoustic wave resonators or packages in accordance with any suitable principles and advantages disclosed herein. Any suitable number of filters 416A to 416N can be implemented. The illustrated filters 416A to 416N are receive filters. In some embodiments (not illustrated), one or more of the filters 416A to 416N can be included in a multiplexer that also includes a transmit filter. The radio frequency switch 417 can be a multi-throw radio frequency switch. The radio frequency switch 417 can electrically couple an output of a selected filter of filters 416A to 416N to the low noise amplifier 418. In some embodiments (not illustrated), a plurality of low noise amplifiers can be implemented. The module 415 can include diversity receive features in certain applications.

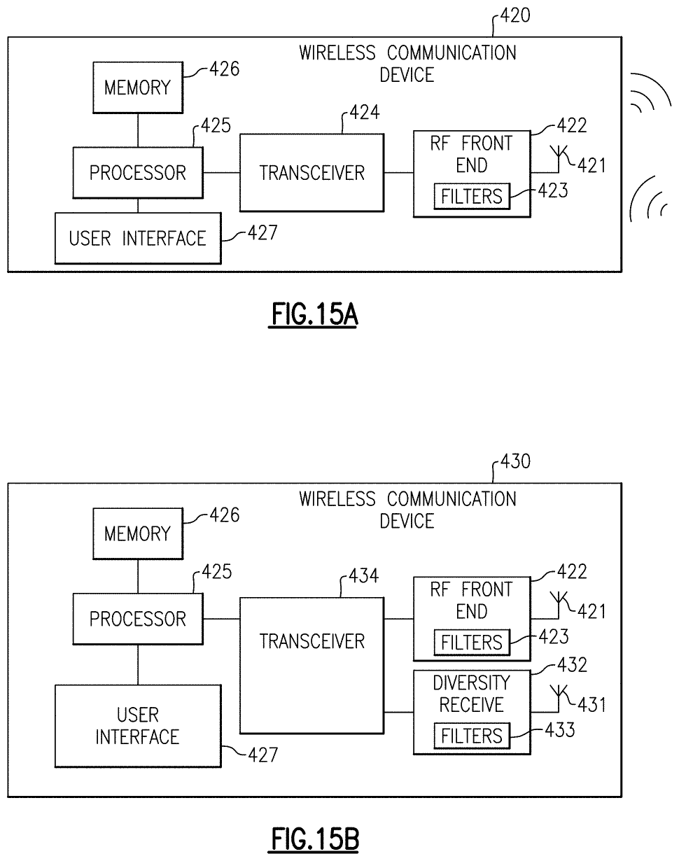

FIG. 15A is a schematic diagram of a wireless communication device 420 that includes filters 423 in a radio frequency front end 422 according to an embodiment. The filters 423 can include one or more SAW resonators or be part of an electronics package with a multi-layer piezoelectric substrate in accordance with any suitable principles and advantages discussed herein. The wireless communication device 420 can be any suitable wireless communication device. For instance, a wireless communication device 420 can be a mobile phone, such as a smart phone. As illustrated, the wireless communication device 420 includes an antenna 421, an RF front end 422, a transceiver 424, a processor 425, a memory 426, and a user interface 427. The antenna 421 can transmit/receive RF signals provided by the RF front end 422. Such RF signals can include carrier aggregation signals. Although not illustrated, the wireless communication device 420 can include a microphone and a speaker in certain applications.

The RF front end 422 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 422 can transmit and receive RF signals associated with any suitable communication standards. The filters 423 can include SAW resonators of a SAW component or electronics package with a multi-layer piezoelectric substrate that includes any suitable combination of features discussed with reference to any embodiments discussed above.

The transceiver 424 can provide RF signals to the RF front end 422 for amplification and/or other processing. The transceiver 424 can also process an RF signal provided by a low noise amplifier of the RF front end 422. The transceiver 424 is in communication with the processor 425. The processor 425 can be a baseband processor. The processor 425 can provide any suitable base band processing functions for the wireless communication device 420. The memory 426 can be accessed by the processor 425. The memory 426 can store any suitable data for the wireless communication device 420. The user interface 427 can be any suitable user interface, such as a display with touch screen capabilities.

FIG. 15B is a schematic diagram of a wireless communication device 430 that includes filters 423 in a radio frequency front end 422 and a second filter 433 in a diversity receive module 432. The wireless communication device 430 is like the wireless communication device 400 of FIG. 15A, except that the wireless communication device 430 also includes diversity receive features. As illustrated in FIG. 15B, the wireless communication device 430 includes a diversity antenna 431, a diversity module 432 configured to process signals received by the diversity antenna 431 and including filters 433, and a transceiver 434 in communication with both the radio frequency front end 422 and the diversity receive module 432. The filters 433 can include one or more SAW resonators or be in or part of an electronics package with a multi-layer piezoelectric substrate that includes any suitable combination of features discussed with reference to any embodiments discussed above.

Although embodiments disclosed herein relate to surface acoustic wave resonators or electronics packages with a multi-layer piezoelectric substrate, any suitable principles and advantages disclosed herein can be applied to other types of acoustic wave resonators that include an IDT electrode, such as Lamb wave resonators and/or boundary wave resonators.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method of making a packaged acoustic wave component comprising:
forming an acoustic wave device including forming or providing a substrate, forming or providing a piezoelectric layer over at least a portion of the substrate, and forming or providing one or more signal lines;
forming a dielectric layer over an outer edge portion of the piezoelectric layer; and
attaching a thermally conductive structure to the substrate and the one or more signal lines, the one or more signal lines interconnecting the piezoelectric layer and the thermally conductive structure, the dielectric layer interposed between the piezoelectric layer and the thermally conductive structure to thereby reduce a stress on the piezoelectric layer from the thermally conductive structure.

2. The method of claim 1 wherein forming the acoustic wave device includes forming or providing a dielectric layer between the substrate and the piezoelectric layer.

3. The method of claim 1 wherein forming the dielectric layer includes interposing the dielectric layer between the one or more signal lines and the piezoelectric layer.

4. The method of claim 1 wherein forming the dielectric layer includes forming the dielectric layer of polyimide.

5. The method of claim 1 wherein the thermally conductive structure includes a metal portion set back from the piezoelectric layer so that one or more pillars are disposed between the metal portion and the piezoelectric layer.

6. The method of claim 1 wherein forming or providing the piezoelectric layer includes forming an outer edge of the piezoelectric layer so that it is spaced inward of an outer edge of the substrate.

7. The method of claim 1 wherein forming or providing the piezoelectric layer includes forming an outer edge of the piezoelectric layer so that it is spaced inward of an inner surface of a metal portion of the thermally conductive structure by a distance of approximately 5-15 microns.

8. The method of claim 1 wherein forming the dielectric layer includes forming the dielectric layer to have a thickness of between about 1 um and about 3 um.

9. The method of claim 1 wherein forming the dielectric layer includes forming the dielectric layer over the piezoelectric layer in non-electrically connected areas of the package.

10. The method of claim 1 wherein forming the dielectric layer includes forming the dielectric layer over the piezoelectric layer in non-electrically connected areas and electrically connected areas of the package.

11. The method of claim 1 wherein forming the dielectric layer includes forming the dielectric layer over the piezoelectric layer around an entire periphery of the package.

12. A method of making a radio frequency module comprising:
forming or providing a package substrate;
forming or providing a packaged acoustic wave component including an acoustic wave device including forming or providing a substrate, forming or providing a piezoelectric layer over at least a portion of the substrate, forming or providing one or more signal lines, forming a dielectric layer over an outer edge portion of the piezoelectric layer, and attaching a thermally conductive structure to the substrate and the one or more signal lines, the one or more signal lines interconnecting the piezoelectric layer and the thermally conductive structure, the dielectric layer interposed between the piezoelectric layer and the thermally conductive structure to thereby reduce a stress on the piezoelectric layer from the thermally conductive structure; and
attaching additional circuitry and the packaged acoustic wave component to the package substrate.

13. The method of claim 12 wherein forming the acoustic wave device includes forming or providing a dielectric layer between the substrate and the piezoelectric layer.

14. The method of claim 12 wherein forming the dielectric layer includes interposing the dielectric layer between the one or more signal lines and the piezoelectric layer.

15. The method of claim 12 wherein forming the dielectric layer includes forming the dielectric layer of polyimide.

16. The method of claim 12 wherein the thermally conductive structure includes a metal portion set back from the piezoelectric layer so that one or more pillars are disposed between the metal portion and the piezoelectric layer.

17. The method of claim 12 wherein forming or providing the piezoelectric layer includes forming an outer edge of the piezoelectric layer so that it is spaced inward of an outer edge of the substrate.

18. The method of claim 12 wherein forming or providing the piezoelectric layer includes forming an outer edge of the piezoelectric layer so that it is spaced inward of an inner surface of a metal portion of the thermally conductive structure by a distance of approximately 5-15 microns.

19. The method of claim 12 wherein forming the dielectric layer includes forming the dielectric layer to have a thickness of between about 1 um and about 3 um.

20. The method of claim 12 wherein forming the dielectric layer includes forming the dielectric layer over the piezoelectric layer in non-electrically connected areas of the package.

21. The method of claim 12 wherein forming the dielectric layer includes forming the dielectric layer over the piezoelectric layer in non-electrically connected areas and electrically connected areas of the package.

22. The method of claim 12 wherein forming the dielectric layer includes forming the dielectric layer over the piezoelectric layer around an entire periphery of the package.
